(19) United States
(12) Patent Application Publication
(10) Pub. No.: US 2026/0173461 A1
(43) Pub. Date: Jun. 18, 2026

(54) HIGH ELECTRON MOBILITY TRANSISTOR WITH THRESHOLD VOLTAGE COMPENSATION REGION

(71) Applicant: Infineon Technologies Austria AG, Villach (AT)

(72) Inventors: Nicholas Stephen Dellas, Villach (AT); Thomas Steffen Rupp, Faak am See (AT); Lichao Teng, Villach (AT)

(21) Appl. No.: 18/981,558

(22) Filed: Dec. 15, 2024

(51) Int. Cl. H10D 62/10; H10D 30/01; H10D 30/47; H10D 62/60; H10D 62/824; H10D 64/27; H10D 84/01; H10D 84/82

(52) U.S. Cl. CPC H10D 62/102; H10D 30/015; H10D 30/475; H10D 62/124; H10D 62/60; H10D 62/824; H10D 64/411; H10D 84/0123; H10D 84/82

(57) ABSTRACT

A semiconductor device includes a substrate including a channel layer of type III-V material and a barrier layer of type III-V material forming a heterojunction interface with the channel layer such that a two-dimensional charge carrier gas is disposed in the channel layer; and one or more high-electron mobility transistors monolithically formed in the semiconductor substrate, wherein each of the high-electron mobility transistors includes a gate structure that comprises a gate electrode and a first doped region of type III-V material arranged between the gate electrode and the barrier layer, wherein the first doped region is configured to generate an electric field that at least partially depletes the two-dimensional charge carrier gas, and wherein one of the high-electron mobility transistors includes a threshold voltage compensation region disposed below the gate structure that is configured to partially compensate for the electric field generated by the first doped region.

### BACKGROUND

Semiconductor transistors, in particular field-effect controlled switching devices such as a MISFET (Metal Insulator Semiconductor Field Effect Transistor), in the following also referred to as MOSFET (Metal Oxide Semiconductor Field Effect Transistor) and an HEMT (high-electron-mobility Field Effect Transistor) also known as heterostructure FET (HFET) and modulation-doped FET (MODFET) are used in a variety of applications. An HEMT is formed from type III-V semiconductor material, e.g., gallium nitride (GaN), gallium arsenide (GaAs), etc. An HEMT includes a two-dimensional charge carrier gas that is created by a heterojunction between two layers of type III-V semiconductor material having different band gaps. This two-dimensional charge carrier gas provides the active device channel that accommodates the load current of the device. Due to the high mobility of carriers within the two-dimensional charge carrier gas, these devices offer very low on-resistance in comparison to other device technologies. For this reason, HEMTs are well suited for power switching applications and/or high frequency applications. HEMTs may be used to control voltages on the order of 5V, 10V, 50V, 100V, 250V, 500V, 1000V, etc. or greater, and/or the control of currents in excess of 1 A, 5 A, 10 A, or greater. HEMTs may be operated at switching frequencies on the order of 10 KHz to 50 GHz. Due to the self-conducting nature of the two-dimensional charge carrier gas, special measures must be taken to create an enhancement mode (normally-off) HEMT transistor.

It is desirable to improve techniques for defining and/or turning the threshold voltage of HEMT devices.

### SUMMARY

A semiconductor device is disclosed. According to an embodiment, the semiconductor device comprises a semiconductor substrate comprising a channel layer of type III-V material and a barrier layer of type III-V material formed on the channel layer and forming a heterojunction interface with the channel layer such that a two-dimensional charge carrier gas is disposed in the channel layer near the heterojunction interface; and one or more high-electron mobility transistors monolithically formed in the semiconductor substrate, wherein each of the one or more high-electron mobility transistors comprise a gate structure configured to control a conductive state of the two-dimensional charge carrier gas, wherein the gate structure comprises a gate electrode and a first doped region of type III-V material arranged between the gate electrode and the barrier layer, wherein the first doped region is configured to generate an electric field that at least partially depletes the two-dimensional charge carrier gas, and wherein at least one of the one or more high-electron mobility transistors comprises a threshold voltage compensation region that is disposed below the gate structure within the barrier layer and is configured to partially compensate for the electric field generated by the first doped region.

A method of forming a semiconductor device is disclosed. According to an embodiment, the method comprises providing a semiconductor substrate comprising a channel layer of type III-V material and a barrier layer of type III-V material formed on the channel layer and forming a heterojunction interface with the channel layer such that a two-dimensional charge carrier gas is disposed in the channel layer near the heterojunction interface; and monolithically forming one or more high-electron mobility transistors in the semiconductor substrate, wherein each of the one or more high-electron mobility transistors comprise a gate structure configured to control a conductive state of the two-dimensional charge carrier gas, wherein the gate structure comprises a gate electrode and a first doped region of type III-V material arranged between the gate electrode and the barrier layer, wherein the first doped region is configured to generate an electric field that at least partially depletes the two-dimensional charge carrier gas, and wherein at least one of the one or more high-electron mobility transistors comprises a threshold voltage compensation region that is disposed below the gate structure within the barrier layer and is configured to partially compensate for the electric field generated by the first doped region.

Of course, the present invention is not limited to the above features and advantages. Those of ordinary skill in the art will recognize additional features and advantages upon reading the following detailed description, and upon viewing the accompanying drawings.

### BRIEF DESCRIPTION OF THE DRAWINGS

FIG. 1 illustrates a high-electron mobility transistor with a threshold voltage compensation region, according to an embodiment.

FIG. 2, which includes FIGS. 2A, 2B, and 2C, illustrates a semiconductor device with multiple high-electron mobility transistors formed in a semiconductor substrate, wherein one of the high-electron mobility transistors comprises a threshold voltage compensation region, according to an embodiment. FIG. 2A illustrates a plan-view of the semiconductor device; FIG. 2B illustrates a cross-sectional view of the semiconductor device along the plane I-I′ identified in FIG. 2A; and FIG. 2C illustrates a cross-sectional view of the semiconductor device along the plane II-II′ identified in FIG. 2A.

FIG. 3, which includes FIGS. 3A, 3B, 3C, illustrates a semiconductor device with a multi-finger high-electron mobility transistor formed in a semiconductor substrate, wherein one of the fingers of transistor comprises a threshold voltage compensation region, according to an embodiment. FIG. 3A illustrates a plan-view of the semiconductor device; FIG. 3B illustrates a cross-sectional view of the semiconductor device along the plane I-I′ identified in FIG. 3A; and FIG. 3C illustrates a cross-sectional view of the semiconductor device along the plane II-II′ identified in FIG. 3A.

FIG. 4, which includes FIGS. 4A, 4B and 4C, illustrates selected method steps in a method for forming a high-electron mobility transistor with a threshold voltage compensation region, according to an embodiment.

FIG. 5, which includes FIGS. 5A and 5B, illustrates a semiconductor device with a multi-finger high-electron mobility transistor formed in a semiconductor substrate, according to an embodiment. FIG. 5A illustrates a plan-view of the semiconductor device; and FIG. 5B illustrates a cross-sectional view of the semiconductor device along the plane I-I′ identified in FIG. 5A.

### DETAILED DESCRIPTION

Embodiments of semiconductor device comprising a high-electron mobility transistor with a threshold voltage compensation region and a corresponding method of forming the semiconductor device are described herein. The incorporation of the threshold voltage compensation region into the device advantageously allows for easy threshold voltage tailoring. This threshold voltage tailoring can be done to a subset of transistors in a multi-transistor device and/or a subset of fingers in a multi-finger device. The gate structure of the high-electron mobility transistor(s) can be designed with a baseline threshold voltage and the threshold voltage compensation regions can be used to locally reduce the threshold voltage of the transistor and/or gate finger as desired. The threshold voltage compensation regions can be easily and reliably formed by a doping process whereby dopants are implanted into the barrier layer underneath the gate structure and the polarity and concentration of these dopants is selected to partially counteract the effect of the gate structure.

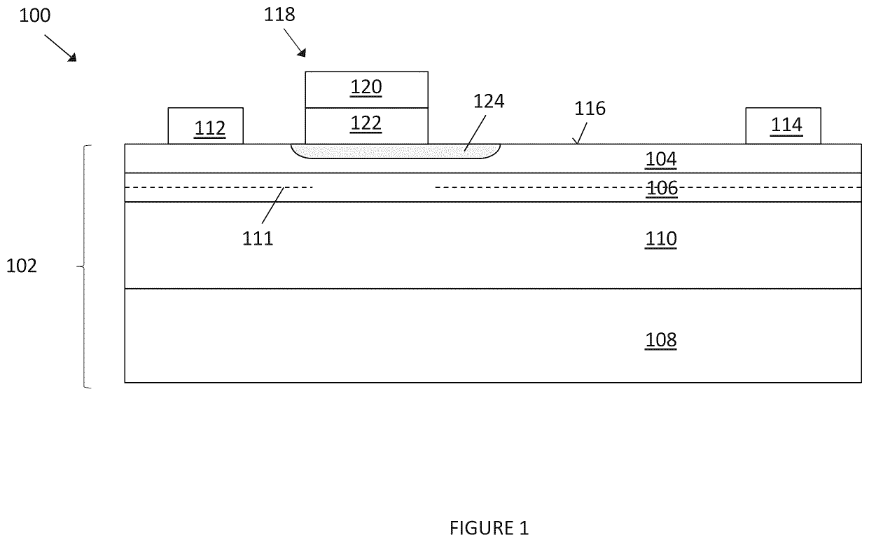

Referring to FIG. 1, a high-electron mobility transistor 100 is shown, according to an embodiment. The high-electron mobility transistor 100 is monolithically formed in a semiconductor substrate 102. The semiconductor substrate 102 comprises a of type III-V material and a barrier layer 104 of type III-V material formed on the channel layer 106. The channel layer 106 and the barrier layer 104 form the active portion of the semiconductor substrate 102. Exemplary III-V semiconductor materials for the barrier layer 104 and the channel layer 106 include gallium nitride (GaN), gallium arsenide (GaAs), aluminium arsenide (AlAs), indium nitride (InN), indium arsenide (InAs), etc., and ternary or quarternary III-V materials such as aluminium gallium nitride (AlGaN), aluminium gallium arsenide (AlGaAs), indium gallium nitride (InGaN), indium aluminium gallium nitride (InAlGaN), etc. The material of the barrier layer 104 has a different bandgap as the channel layer 106 so as to form a heterojunction interface between the barrier layer 104 and the channel layer 106 and thereby form a two-dimensional charge carrier gas 111 forms within the channel layer 106 near the heterojunction interface. The bandgap difference may be realized by using type III-V materials with a difference in metal alloy concentration, e.g., e.g., a difference in aluminum content, indium content, etc.

The semiconductor substrate 102 additionally comprises regions below the active portion formed by the channel layer 106 and the barrier layer 104. These regions comprise a base substrate 108 and an intermediate region 110 disposed in between the base substrate 108 and the active region. The base substrate 108 is used to epitaxially grow type III-V nitride semiconductor material thereon. The base substrate 108 may be provided from a commercially available semiconductor wafer, such as a bulk silicon wafer or a SOI (silicon on insulator) wafer. This base substrate 108 may comprise a variety of semiconductor materials such as silicon (Si), sapphire, silicon carbide (SIC) or silicon germanium (SiGe), etc. The intermediate region 110 comprises one or more regions or layers that may serve a variety of purposes, e.g., lattice mismatch, leakage suppression, performance improvement, etc. For example, the intermediate region 110 may comprise a lattice transition region that is configured to alleviate mechanical stress attributable to crystalline lattice mismatch between the base substrate 108 and the active region comprising the barrier layer 104 and the channel layer 106. Separately or in combination, the intermediate region 110 may comprise a back-barrier layer that interfaces with a lower side of the channel layer 106 and is configured to increase carrier confinement in the channel layer 106 and prevent leakage through lower part of the semiconductor substrate 102. This back-barrier layer may comprise AlGaN with a higher aluminum content than the channel layer 106 and may optionally be doped with C and or Fe, for example.

The high-electron mobility transistor 100 comprises source and drain electrodes 112, 114 that are disposed on the upper surface 116 of the semiconductor substrate 102. The source and drain electrodes 112, 114 are laterally spaced apart from one another in a current flow direction of the device. The source and drain electrodes 112, 114 are each in electrical contact with the two-dimensional charge carrier gas 111. This electrical contact may be effectuated by trenches that extend into the upper surface 116 of the semiconductor substrate 102 (not shown in FIG. 1) and are filled with a conductive metal or doped semiconductor. The connection between the source and drain electrodes 112, 114 may be a low-ohmic (i.e., non-rectifying) connection, or may have rectifying (i.e., Schottky) behavior).

The high-electron mobility transistor 100 comprises a gate structure 118 that is disposed on upper surface 116 of the semiconductor substrate 102 laterally in between the source and drain electrodes 112, 114. The gate structure 118 comprises a gate electrode 120 and a first doped region 122 arranged between the gate electrode 120 and the barrier layer 104. The gate electrode 120 may be formed from an electrically conductive material, e.g., tungsten, aluminum, titanium, titanium nitride, highly doped monocrystalline or polycrystalline semiconductors, etc. The first doped region 122 is a region of type III-V material that is doped with first conductivity type dopants, i.e., dopant atoms which have a first conductivity type in the underlying type III-V material of the first doped region 122, e.g., GaN, AlGaN, etc. The first conductivity type dopants may comprise group 2 elements such as Mg, Ca, etc., and/or may comprise group 12 elements such as such as Zn, Cd, etc. According to an embodiment, the first doped region 122 is a region of p-type GaN or alloys thereof, e.g., p-type AlGaN, wherein the first conductivity type dopants may comprise Mg dopant atoms.

The first doped region 122 of the gate structure 118 is configured to generate an electric field that at least partially depletes the two-dimensional charge carrier gas 111. That is, the first doped region 122 is configured to alter the normal conduction state of the two-dimensional charge carrier gas 111. The first conductivity type dopants generate an electric field that repels carriers in the two-dimensional charge carrier gas, thereby making the two-dimensional charge carrier gas underneath the gate structure less conductive or non-conductive at zero gate bias. According to an embodiment, the first doped region 122 is configured to completely deplete the two-dimensional charge carrier gas 111 in the absence of gate bias, thereby realizing an enhancement mode (normally-off device) configuration. The strength of this electric field and hence threshold voltage of the device is dependent on physical parameters of the first doped region 122 and/or the section of the barrier layer 104 between the gate structure 118 and the heterojunction interface. Examples of these physical parameters include the thickness of first doped region 122, dopant concentration of the first doped region 122, and the thickness of the barrier layer 104 between the gate structure 118 and the heterojunction interface. In the depicted embodiment, the barrier layer 104 has a uniform thickness underneath. In other embodiments, the gate structure 118 may be arranged within a trench in the barrier layer 104, thereby bringing the gate structure closer to the two-dimensional charge carrier gas 111.

The high-electron mobility transistor 100 may comprise additional layers and/or structures on the upper surface 116 of the semiconductor substrate 102 that are not shown for the sake of simplicity. These additional layers and/or structures may comprise further semiconductor layers, e.g., capping layers, electrically insulating layers and/or protective layers, e.g., passivation layers, interlayer dielectrics, etc., metallization layers, e.g., metal contact pads, bond pads, etc.

The working principle of the high-electron mobility transistor 100 is as follows. The gate structure 118 is configured to control a conductive connection between the source and drain electrodes 112, 114 by controlling a conductive state of the two-dimensional charge carrier gas 111. The gate structure 118 provides on/off control by controlling an electric that depletes or repopulates two-dimensional charge carrier gas 111 of carriers underneath the gate structure 118. In the case of an enhancement mode (normally-off) device, the two-dimensional charge carrier gas 111 is depleted underneath the two-dimensional charge carrier gas 111 at zero gate-source bias. The device is turned on by applying a gate-source bias that alters the electric field underneath the gate structure 118, thereby populating the two-dimensional charge carrier gas 111 underneath the gate structure 118 and completing the electrical connection between the source and drain electrodes 112, 114. A normally-on device works similarly, except that a negative gate bias is applied to the gate structure 118 to deplete the two-dimensional charge carrier gas 111 underneath the gate structure 118 and thereby turn the device off.

The high-electron mobility transistor 100 additionally comprises a threshold voltage compensation region 124 disposed below the gate structure 118 within the barrier layer 104. The threshold voltage compensation region 124 is configured to at least partially compensate for the electric field generated by the first doped region 122. That is, the electric field that is used to deplete the two-dimensional charge carrier gas 111 is at least partially mitigated by the threshold voltage compensation region 124. For example, a high-electron mobility transistor 100 that is devoid of the threshold voltage compensation region 124 but otherwise identical to the device shown in FIG. 1 may have a given threshold voltage (e.g., 2V), whereas the same high-electron mobility transistor 100 comprising the threshold voltage compensation region 124 has a lower threshold voltage (e.g., 1V), due to the influence of the threshold voltage compensation region 124.

According to an embodiment, the threshold voltage compensation region 124 comprises a concentration of second conductivity type dopant atoms i.e., dopant atoms with a conductivity type opposite from the first conductivity type dopants provided in the first doped region 122. For example, in the case that the first doped region 122 is a p-type region, the threshold voltage compensation region 124 may comprise a concentration of n-type dopants within the barrier layer 104. The second conductivity type dopants may comprise group 4 elements such as Si, Ge and Sn. By providing the concentration of second conductivity type dopant atoms within the barrier layer 104 between the first doped region 122 and the heterojunction interface, the threshold voltage compensation region 124 serves to partially counterbalance the first conductivity type charges within the first doped region 122 and thereby reduce the strength of the electric field of the first doped region 122. The selected physical parameters such as second conductivity type dopant concentration, thickness of the barrier layer, etc., this can be tailored to achieve a desired reduction in threshold voltage compensation region 124 in comparison to a device that does not include the threshold voltage compensation region 124. In fact, this concept can be used to completely negate the impact of the first doped region 122 and/or create a depletion mode (normally-on) device.

The threshold voltage compensation region 124 extends to an upper face of the barrier layer that faces the first doped region 122. As shown, this upper face corresponds to the upper surface 116 of the semiconductor substrate 102. The threshold voltage compensation region 124 may be created by implanting second conductivity type dopants into the upper surface of the barrier layer. e.g., according to a technique that will be described in further detail below. The threshold voltage compensation region 124 is spaced apart from the heterojunction interface. That is, an undoped portion of the barrier is provided between a lower side of the threshold voltage compensation region 124 and the heterojunction interface so as to prevent the channel layer 106 from being contaminated by second conductivity type dopants.

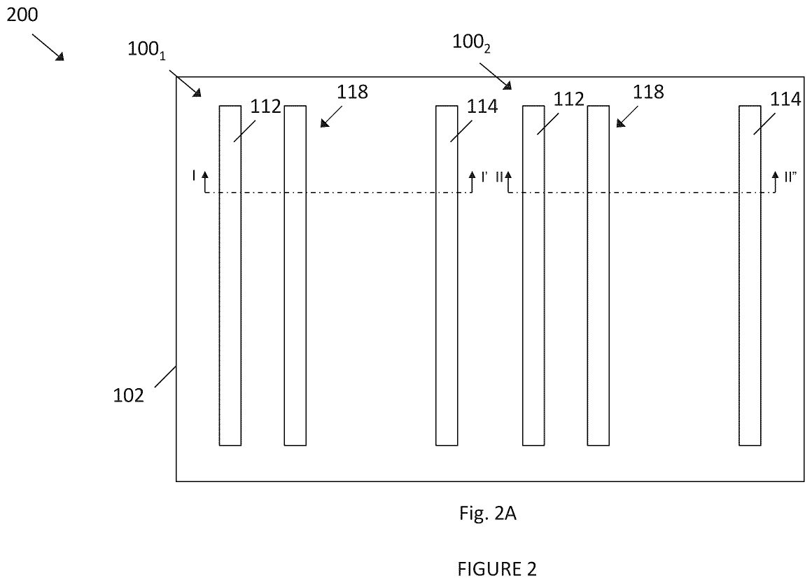

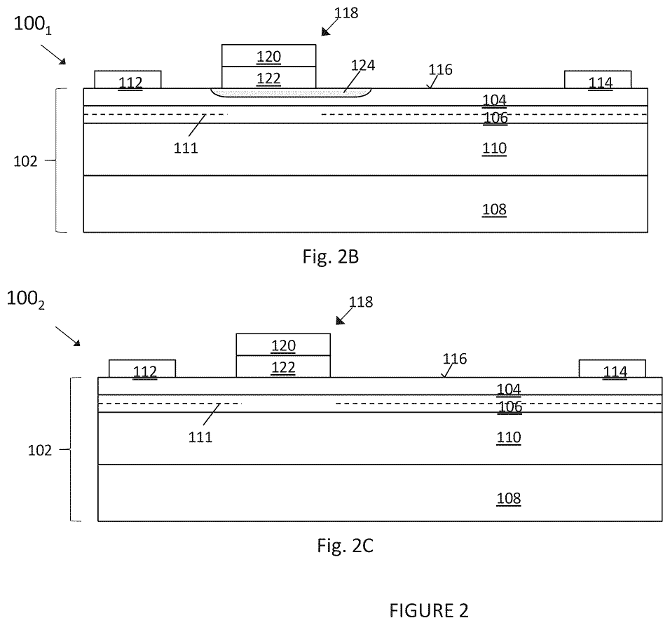

Referring to FIG. 2, a semiconductor device 200 is shown, according to an embodiment. The semiconductor device 200 comprises a first high-electron mobility transistor 1001 and a second high-electron mobility transistor 1002 that are each formed in a single semiconductor substrate 102. These transistor devices can be configured to operate independent from one another and used for different purposes. For example, according to an embodiment, the second high-electron mobility transistor 1002 may be configured as a power transistor and the second high-electron mobility transistor 1002 may be configured as a driver device that is configured to control a switching operation of the first high-electron mobility transistor 1001. In that case, the second high-electron mobility transistor 1002 is rated to control operating voltages associated with power applications, e.g., voltages on the order of 5V, 10V, 50V, 100V, 250V, 500V, 1000V, etc. or greater, while the first high-electron mobility transistor 1001 may have a much lower voltage rating, e.g., voltages less than 10V, less than 5V, etc. It should be appreciated that the depicted layout is not necessarily drawn to scale, and in principle the size/geometry, etc. of each device may vary significantly.

The semiconductor device 200 is configured such that the threshold voltage of the first high-electron mobility transistor 1001 is lower than the threshold voltage of the second high-electron mobility transistor 1002. For example, in an embodiment, both of the first and second high-electron mobility transistors are configured as enhancement mode normally-off) devices, with the first high-electron mobility transistor 1001 being lower than the second high-electron mobility transistor 1002. For example, the first high-electron mobility transistor 1001 may have a threshold voltage of less than 1V, less than 0.5V or less than OV (i.e., depletion mode), whereas the second high-electron mobility transistor 1002 may have a threshold volage on the order of 1.0V to 2.0V.

The difference in threshold voltage between the first high-electron mobility transistor 1001 and the second high-electron mobility transistor 1002 results from the provision of the threshold voltage compensation region 124. That is, the first high-electron mobility transistor 1001 and the second high-electron mobility transistor 1002 can otherwise be configured as identical devices and/or created by identical processing steps, with the only difference being the presence of the threshold voltage compensation region 124. In this way, a monolithically integrated solution for multiple devices is provided, wherein a difference in threshold voltage can be adjusted at minimal expense. In the depicted embodiment, the semiconductor device 200 is configured such thar the first high-electron mobility transistor comprises the threshold voltage compensation region 124 and the second high-electron mobility transistor is devoid of the threshold voltage compensation region 124, i.e., there is no intentional doping introduced into the barrier layer 104 between the gate structure 118 and the heterojunction interface. As a result, the second high-electron mobility transistor 1002 has a baseline threshold voltage, and the incorporation of the threshold voltage compensation region 124 into the first high-electron mobility transistor shifts the baseline threshold voltage downward.

In addition to the depicted embodiment, the compensation region concept may be used in a variety of ways to selectively tailor the threshold voltage of devices. For example, in another embodiment, each of the first high-electron mobility transistor 1001 and the second high-electron mobility transistor 1002 comprise the threshold voltage compensation region 124, while the parameters (e.g., dopant concentration, depth, size, etc.) of the threshold voltage compensation region 124 used in the second high-electron mobility transistor 1002 are different from the threshold voltage compensation region 124 used in the first high-electron mobility transistor 1001. Separately or in combination, the semiconductor device 200 may comprise more than two transistors with different threshold voltages that results from the presence and/or properties of the threshold voltage compensation region 124 incorporated therein.

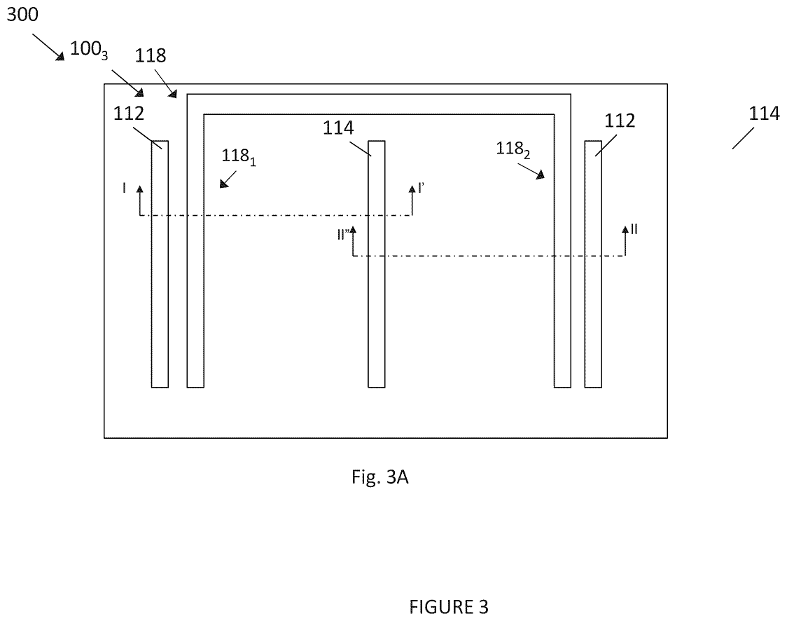

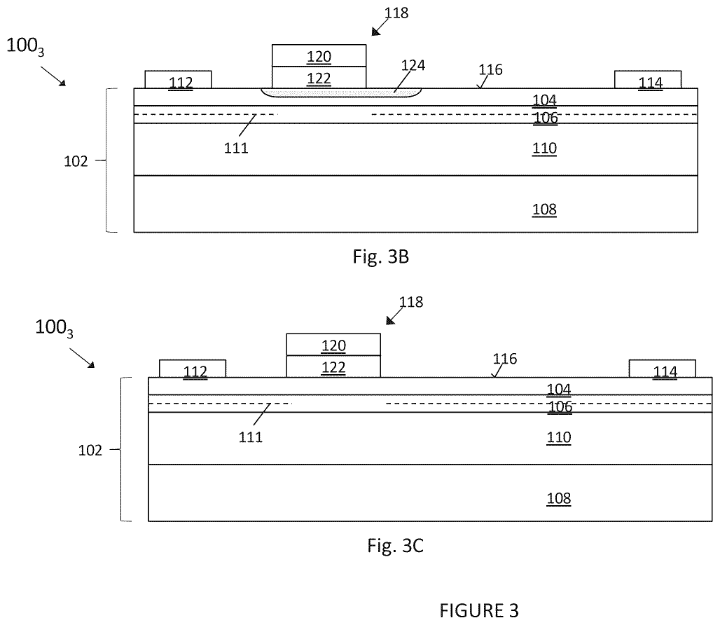

Referring to FIG. 3, a semiconductor device 300 is shown, according to an embodiment. The semiconductor device 300 comprises a multi-finger high-electron mobility transistor. A multi-finger high-electron mobility transistor refers to a device that comprises multiple electrode structures that accommodate the operational current of the device in parallel, thereby increasing its current carrying capability. As shown, the gate structure 118 of the multi-finger high-electron mobility transistor comprises a first gate finger 1181 and a second gate finger 1182. The device is arranged with two separate source electrodes 112 arranged on either side of a common drain electrode 114, wherein each of the first gate finger 1181 and a second gate finger 1182 are configured to control current flowing towards the drain electrode 114 based on a similar operational principle as described above. Other multi-finger high-electron mobility transistor arrangements include so-called common source configurations wherein the current flow principle is reversed. Moreover, while the illustrated example shows a device with two fingers, the same concept may be repeated many more times to create devices with three, four, five, etc. fingers. The threshold voltage modulation concept described herein can be incorporated into any of these device concepts.

The semiconductor device 300 is configured such that the threshold voltage of that first gate finger 1181 is lower than the threshold voltage of the second gate finger 1182. That is, the first gate finger 1181 is arranged to become conductive at a lower gate-source voltage than the second gate finger 1182. This arrangement may provide certain benefits. For example, so-called third quadrant losses may degrade performance, particularly in high frequency applications. The selective lowering of the threshold voltage in certain fingers of the device facilitates faster turn-on and hence reduces third quadrant losses without recognizing the full penalty of uniformly lowering the threshold of the device, which may have drawbacks such as increased leakage current.

As shown in FIGS. 3A and 3B, the difference in the threshold voltage is realized through the provision of the threshold voltage compensation region 124 in a similar manner as described above. In this case, the semiconductor device 300 is configured such that the multi-finger high-electron mobility transistor 300 comprises the threshold voltage compensation region 124 disposed below the first gate finger 1181, whereas the second gate finger 1182 of the multi-finger high-electron mobility transistor 300 is devoid of the threshold voltage compensation region 124. Other arrangements are contemplated by this concept. For example, in another embodiment, each of the first gate finger 1181 and the second gate finger 1182 comprise the threshold voltage compensation region 124, while the parameters (e.g., dopant concentration, depth, etc.) of the threshold voltage compensation region 124 used in the second gate finger 1182 are different from the threshold voltage compensation region 124 used in the first gate finger 1181. Separately or in combination, the semiconductor device 200 may comprise more than two fingers that with different threshold voltages that results from the presence and/or properties of the threshold voltage compensation region 124 incorporated therein.

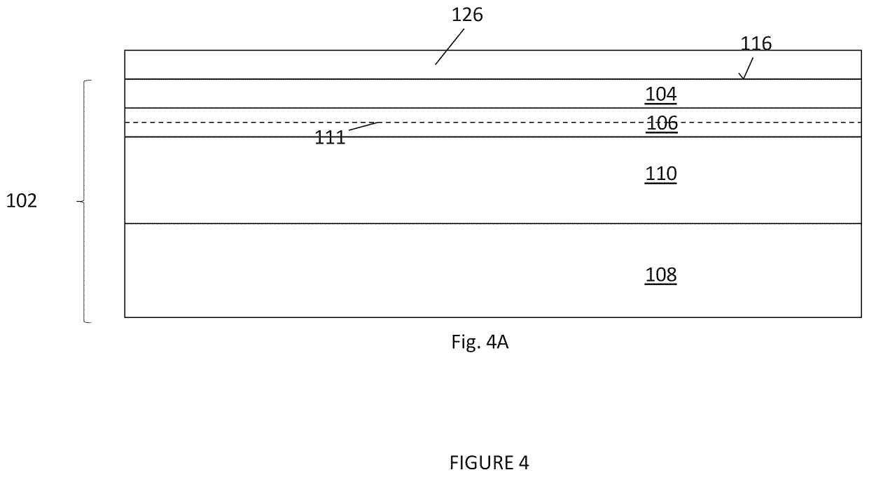

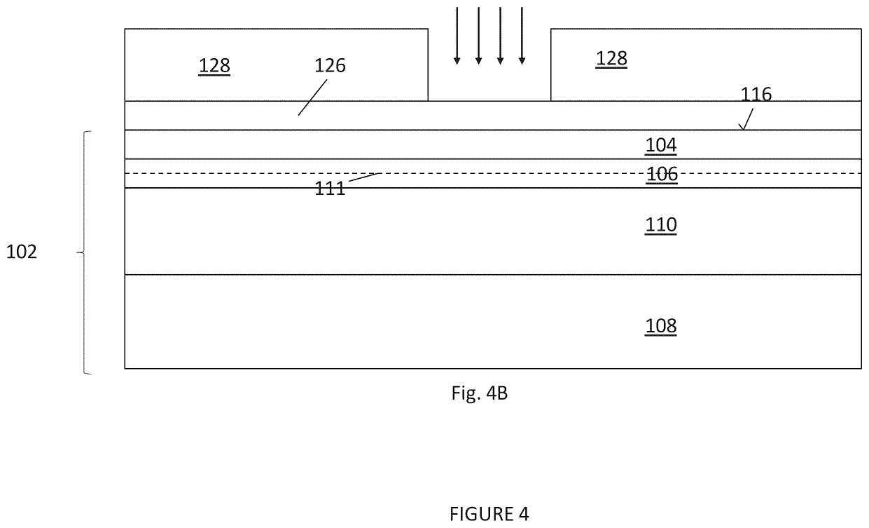

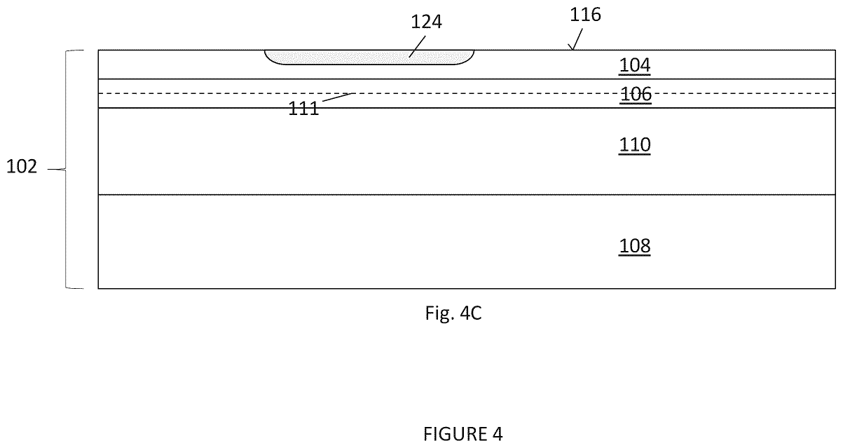

Referring to FIG. 4, method of forming a semiconductor device with at least one threshold voltage compensation region 124 is shown, according to an embodiment.

Referring to FIG. 4A, a semiconductor substrate 102 comprising a barrier layer 104 and a channel layer 106 is provided. The semiconductor substrate 102 can be configured according to any of the embodiments described above. After providing the semiconductor substrate 102, a blanket implant layer 126 is formed on the barrier layer. The blanket implant layer 126 is a layer that is configured to absorb/suppress implantation of second conductivity type dopant atoms into the barrier layer 104 and thereby cause most of the implanted dopant atoms to be located near the surface of the barrier layer 104. According to an embodiment, the blanket implant layer 126 is a layer of insulating material. For example, the blanket implant layer 126 may comprise a TEOS layer, i.e. a layer that is deposited using a TEOS (Tetraethyl orthosilicate) process. Generally speaking, the blanket implant layer 126 may have a thickness in the range of 5 nm to 100 nm. According to an embodiment, the blanket implant layer 126 is a TEOS layer with a thickness in the range of 10 nm to 30 nm, or more particularly a thickness of about 20 nm.

Referring to FIG. 4B, a structured mask 128 is formed on the blanket implant layer 126. The structured mask 128 is patterned to include one or more openings that expose the upper surface of the semiconductor substrate 102. The structured mask 128 can be formed using any kind of photography technique. For example, the structured mask 128 can be a so-called soft photoresist material, e.g. an organic polymer-based material, that is directly lithographically defined on the blanket implant layer 126. A thickness of this photoresist material may be in the range of 100 nm to 10 μm, more particularly in the range of 500 nm to 5 μm, more particularly in the range of 500 nm to 2 μm, more particularly about 1 μm. Alternatively, the structured mask 128 can be formed from a so-called hard mask material, e.g., silicon dioxide, silicon oxynitride, etc., that is initially formed as a blanket layer and defined by a photography technique. A thickness of this hard mask material may be in the range of 100 nm to 5 μm.

After forming the structured mask 128, an implantation process is performed to implant second conductivity type dopant atoms, i.e., dopant atoms which have a second conductivity type in the material of the barrier layer 104, through openings in the structured mask 128 and through the blanket implant layer 126. As mentioned above, dopant atoms which have a second conductivity type in the material of the barrier layer 104 comprise group 4 elements such as Si, Ge and Sn. According to an embodiment, the dopant atoms are silicon atoms. Parameters of the implantation process, e.g., implantation energy, implantation angle, et. are selected to cause the dopant atoms to penetrate the blanket implant layer 126 and create a desired concentration near the surface of the barrier layer 104, while preventing a statistically significant amount of dopant atoms from reaching the heterojunction interface. Using silicon dopant atoms and blanket implant layer 126 with a thickness of about 20 nm as an example, an implant energy of about 15 KeV may be used. In this case, a peak concentration of the silicon dopant atoms occurs at a depth within the blanket implant layer 126, wherein the upper surface of the barrier layer 104 coincides to a location in which the dopant concentration is decreasing with further depth and the complete distribution of the dopant atoms penetrates the barrier layer 104 by no more than about 400-600 A. Meanwhile, the thickness of the barrier layer 104 may be on the order of about 15-20 nm, e.g., about 18 nm. Thus, the implanted dopant atoms are maintained at a significant distance from the heterojunction interface.

Referring to FIG. 4C, the structured mask 128 and the blanket implant layer 126 are removed from the semiconductor substrate 102. This may be done by etching, CMP, etc. After removal, the further features of the device including the source and drain electrodes 112, 114 and the gate structure gate structure 118. As shown in FIG. 1, the gate structure is formed to at least partially overlap with the compensation region 124. If desired, the compensation region 124 may be formed to extend past the gate structure 118 and into the access region of the device. For devices and/or gate fingers that are formed to be devoid of the compensation region 124, the process shown in FIG. 1 can be performed with the structured mask 128 covering the gate region of these devices and/or gate fingers.

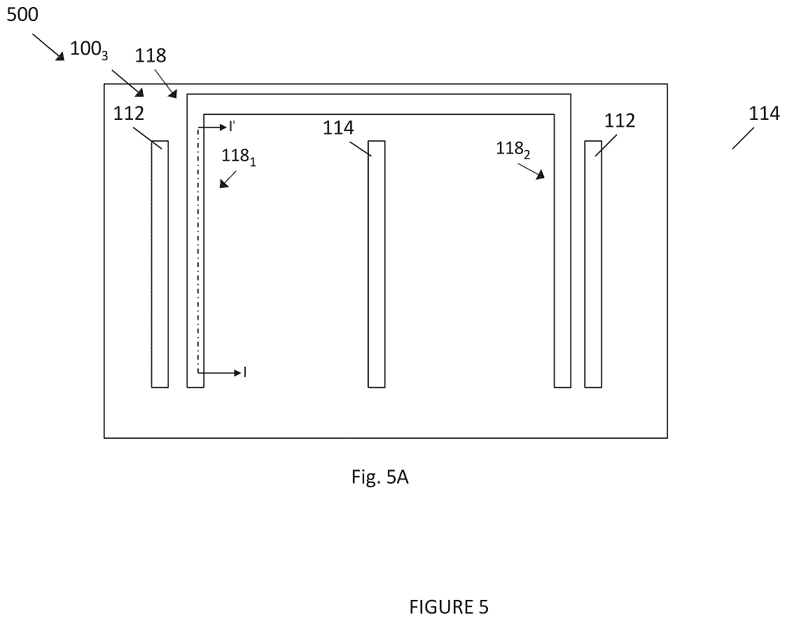

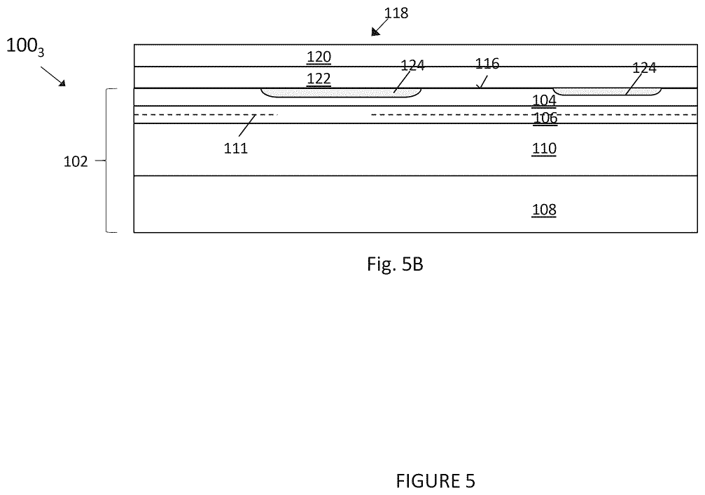

Referring to FIG. 5, a semiconductor device 500 is shown, according to an embodiment. The semiconductor device 500 comprises a multi-finger high-electron mobility transistor. In this embodiment, the semiconductor device 500 is configured such that the threshold voltage of the first gate finger 1181 is locally varied along a lengthwise direction of the first gate finger 1181. As shown in FIG. 5B, the lengthwise variation in the threshold voltage is realized by multiple threshold voltage compensation regions 124 extending in the lengthwise direction. That is, the threshold voltage compensation regions 124 are provided with at least some interruptions. In principle, the frequency and spacing of the threshold voltage compensation regions 124 can be adjusted to obtain a desired threshold voltage of a particular gate finger. This frequency and spacing of the threshold voltage compensation regions 124 can be varied in other gate fingers to achieve variation as between multiple gate fingers. For example, the first gate finger 1182 may comprise different lengths, numbers, spacings, etc. of the threshold voltage compensation regions 124.

Although the present disclosure is not so limited, the following numbered examples demonstrate one or more aspects of the disclosure.

Example 1. A semiconductor device, comprising: a semiconductor substrate comprising a channel layer of type III-V material and a barrier layer of type III-V material formed on the channel layer and forming a heterojunction interface with the channel layer such that a two-dimensional charge carrier gas is disposed in the channel layer near the heterojunction interface; and one or more high-electron mobility transistors monolithically formed in the semiconductor substrate, wherein each of the one or more high-electron mobility transistors comprise a gate structure configured to control a conductive state of the two-dimensional charge carrier gas, wherein the gate structure comprises a gate electrode and a first doped region of type III-V material arranged between the gate electrode and the barrier layer, wherein the first doped region is configured to generate an electric field that at least partially depletes the two-dimensional charge carrier gas, and wherein at least one of the one or more high-electron mobility transistors comprises a threshold voltage compensation region that is disposed below the gate structure within the barrier layer and is configured to partially compensate for the electric field generated by the first doped region.

Example 2. The semiconductor device of example 1, wherein the first doped region from each of the one or more high-electron mobility transistors has a first conductivity type dopant concentration, and wherein the threshold voltage compensation region comprises a concentration of second conductivity type dopant atoms disposed within the barrier layer between the first doped region and the heterojunction interface.

Example 3. The semiconductor device of example 2, wherein the threshold voltage compensation region is a second conductivity type region that extends to an upper face of the barrier layer that faces the first doped region and is spaced apart from the heterojunction interface.

Example 4. The semiconductor device of example 2, wherein the second conductivity type dopant atoms comprise silicon dopant atoms.

Example 5. The semiconductor device of example 2, wherein the channel layer is a layer of GaN or AlGaN, wherein the barrier layer is a region of AlGaN with a higher aluminum content than the channel layer, and wherein the first doped region from each of the one or more high-electron mobility transistors is a region of p-type GaN.

Example 6. The semiconductor device of example 1, wherein the one or more high-electron mobility transistors comprises a first high-electron mobility transistor and a second high-electron mobility transistor, wherein the first high-electron mobility transistor comprises the threshold voltage compensation region, and wherein a threshold voltage of the first high-electron mobility transistor is lower than a threshold voltage of the second high-electron mobility transistor.

Example 7. The semiconductor device of example 6, wherein the second high-electron mobility transistor is devoid of the threshold voltage compensation region.

Example 8. The semiconductor device of example 6, wherein both of the first and second high-electron mobility transistors are configured as enhancement mode devices.

Example 9. The semiconductor device of example 1, wherein the one or more high-electron mobility transistors comprises a multi-finger high-electron mobility transistor, wherein the gate structure of the multi-finger high-electron mobility transistor comprise a first gate finger and a second gate finger, wherein the multi-finger high-electron mobility transistor comprises the threshold voltage compensation region disposed below the first gate finger.

Example 10. The semiconductor device of example 9, wherein the second gate finger of the multi-finger high-electron mobility transistor is devoid of the threshold voltage compensation region.

Example 11. A method of forming a semiconductor device, the method comprising: providing a semiconductor substrate comprising a channel layer of type III-V material and a barrier layer of type III-V material formed on the channel layer and forming a heterojunction interface with the channel layer such that a two-dimensional charge carrier gas is disposed in the channel layer near the heterojunction interface; and monolithically forming one or more high-electron mobility transistors in the semiconductor substrate, wherein each of the one or more high-electron mobility transistors comprise a gate structure configured to control a conductive state of the two-dimensional charge carrier gas, wherein the gate structure comprises a gate electrode and a first doped region of type III-V material arranged between the gate electrode and the barrier layer, wherein the first doped region is configured to generate an electric field that at least partially depletes the two-dimensional charge carrier gas, and wherein at least one of the one or more high-electron mobility transistors comprises a threshold voltage compensation region that is disposed below the gate structure within the barrier layer and is configured to partially compensate for the electric field generated by the first doped region.

Example 12. The method of example 11, wherein the first doped region from each of the one or more high-electron mobility transistors has a first conductivity type dopant concentration, and wherein the threshold voltage compensation region comprises a concentration of second conductivity type dopant atoms disposed within the barrier layer between the first doped region and the heterojunction interface.

Example 13. The method of example 12, wherein the threshold voltage compensation region is a second conductivity type region that extends to an upper face of the barrier layer that faces the first doped region and is spaced apart from the heterojunction interface.

Example 14. The method of example 12, wherein the second conductivity type dopant atoms comprise silicon dopant atoms.

Example 15. The method of example 12, wherein the channel layer is a layer of GaN or AlGaN, wherein the barrier layer is a region of AlGaN with a higher aluminum content than the channel layer, and wherein the first doped region from each of the one or more high-electron mobility transistors is a region of p-type GaN.

Example 16. The method of example 11, wherein forming the threshold voltage compensation region comprises: forming a blanket implant layer on the barrier layer; forming a structured mask on the blanket implant layer; and implanting second conductivity type dopant atoms through openings in the structured mask and into the blanket implant layer.

Example 17. The method of example 16, further comprising removing the blanket implant layer after the implanting second conductivity type dopant atoms, and wherein the method further comprises forming the gate structure for the one or more high-electron mobility transistors after removing the blanket implant layer.

Example 18. The method of example 16, wherein the blanket implant layer is an oxide layer with a thickness of between 10 nm and 30 nm.

Notably, modifications and other embodiments of the disclosed invention(s) will come to mind to one skilled in the art having the benefit of the teachings presented in the foregoing descriptions and the associated drawings. Therefore, it is to be understood that the invention(s) is/are not to be limited to the specific embodiments disclosed and that modifications and other embodiments are intended to be included within the scope of this disclosure. Although specific terms may be employed herein, they are used in a generic and descriptive sense only and not for purposes of limitation.

What is claimed is:

1. A semiconductor device, comprising:
a semiconductor substrate comprising a channel layer of type III-V material and a barrier layer of type III-V material formed on the channel layer and forming a heterojunction interface with the channel layer such that a two-dimensional charge carrier gas is disposed in the channel layer near the heterojunction interface; and
one or more high-electron mobility transistors monolithically formed in the semiconductor substrate,
wherein each of the one or more high-electron mobility transistors comprise a gate structure configured to control a conductive state of the two-dimensional charge carrier gas,
wherein the gate structure comprises a gate electrode and a first doped region of type III-V material arranged between the gate electrode and the barrier layer,
wherein the first doped region is configured to generate an electric field that at least partially depletes the two-dimensional charge carrier gas, and wherein at least one of the one or more high-electron mobility transistors comprises a threshold voltage compensation region that is disposed below the gate structure within the barrier layer and is configured to partially compensate for the electric field generated by the first doped region.

2. The semiconductor device of claim 1, wherein the first doped region from each of the one or more high-electron mobility transistors has a first conductivity type dopant concentration, and wherein the threshold voltage compensation region comprises a concentration of second conductivity type dopant atoms disposed within the barrier layer between the first doped region and the heterojunction interface.

3. The semiconductor device of claim 2, wherein the threshold voltage compensation region is a second conductivity type region that extends to an upper face of the barrier layer that faces the first doped region and is spaced apart from the heterojunction interface.

4. The semiconductor device of claim 2, wherein the second conductivity type dopant atoms comprise silicon dopant atoms.

5. The semiconductor device of claim 2, wherein the channel layer is a layer of GaN or ALGaN, wherein the barrier layer is a region of AlGaN with a higher aluminum content than the channel layer, and wherein the first doped region from each of the one or more high-electron mobility transistors is a region of p-type GaN.

6. The semiconductor device of claim 1, wherein the one or more high-electron mobility transistors comprises a first high-electron mobility transistor and a second high-electron mobility transistor, wherein the first high-electron mobility transistor comprises the threshold voltage compensation region, and wherein a threshold voltage of the first high-electron mobility transistor is lower than a threshold voltage of the second high-electron mobility transistor.

7. The semiconductor device of claim 6, wherein the second high-electron mobility transistor is devoid of the threshold voltage compensation region.

8. The semiconductor device of claim 6, wherein both of the first and second high-electron mobility transistors are configured as enhancement mode devices.

9. The semiconductor device of claim 1, wherein the one or more high-electron mobility transistors comprises a multi-finger high-electron mobility transistor, wherein the gate structure of the multi-finger high-electron mobility transistor comprise a first gate finger and a second gate finger, wherein the multi-finger high-electron mobility transistor comprises the threshold voltage compensation region disposed below the first gate finger.

10. The semiconductor device of claim 9, wherein the second gate finger of the multi-finger high-electron mobility transistor is devoid of the threshold voltage compensation region.

11. A method of forming a semiconductor device, the method comprising:
providing a semiconductor substrate comprising a channel layer of type III-V material and a barrier layer of type III-V material formed on the channel layer and forming a heterojunction interface with the channel layer such that a two-dimensional charge carrier gas is disposed in the channel layer near the heterojunction interface; and
monolithically forming one or more high-electron mobility transistors in the semiconductor substrate,
wherein each of the one or more high-electron mobility transistors comprise a gate structure configured to control a conductive state of the two-dimensional charge carrier gas,
wherein the gate structure comprises a gate electrode and a first doped region of type III-V material arranged between the gate electrode and the barrier layer,
wherein the first doped region is configured to generate an electric field that at least partially depletes the two-dimensional charge carrier gas, and wherein at least one of the one or more high-electron mobility transistors comprises a threshold voltage compensation region that is disposed below the gate structure within the barrier layer and is configured to partially compensate for the electric field generated by the first doped region.

12. The method of claim 11, wherein the first doped region from each of the one or more high-electron mobility transistors has a first conductivity type dopant concentration, and wherein the threshold voltage compensation region comprises a concentration of second conductivity type dopant atoms disposed within the barrier layer between the first doped region and the heterojunction interface.

13. The method of claim 12, wherein the threshold voltage compensation region is a second conductivity type region that extends to an upper face of the barrier layer that faces the first doped region and is spaced apart from the heterojunction interface.

14. The method of claim 12, wherein the second conductivity type dopant atoms comprise silicon dopant atoms.

15. The method of claim 12, wherein the channel layer is a layer of GaN or AlGaN, wherein the barrier layer is a region of AlGaN with a higher aluminum content than the channel layer, and wherein the first doped region from each of the one or more high-electron mobility transistors is a region of p-type GaN.

16. The method of claim 11, wherein forming the threshold voltage compensation region comprises:
forming a blanket implant layer on the barrier layer;
forming a structured mask on the blanket implant layer; and
implanting second conductivity type dopant atoms through openings in the structured mask and into the blanket implant layer.

17. The method of claim 16, further comprising removing the blanket implant layer after the implanting second conductivity type dopant atoms, and wherein the method further comprises forming the gate structure for the one or more high-electron mobility transistors after removing the blanket implant layer.

18. The method of claim 16, wherein the blanket implant layer is an oxide layer with a thickness of between 10 nm and 30 nm.
